(19) United States
(12) Patent Application Publication
(10) Pub. No.: US 2016/0336923 A1
(43) Pub. Date: Nov. 17, 2016

(54) PHASE LOCKED LOOP WITH LOW PHASE-NOISE

(71) Applicant: Aura Semiconductor Pvt. Ltd, Bangalore (IN)

(72) Inventors: ANKIT SEEDHER, Bangalore (IN); Raja Prabhu J, Bangalore (IN); Sriharsha Vasadi, Bangalore (IN); Augusto Marques, Bangalore (IN); Srinath Sridharan, Bangalore (IN)

(21) Appl. No.: 15/051,675

(22) Filed: Feb. 24, 2016

(30) Foreign Application Priority Data
May 11, 2015 (IN) 2397/CHE/2015

(51) Int. Cl. H03K 3/013; H03L 7/089; H03L 7/18; H03L 7/091; H03L 7/08; H03L 7/081

(52) U.S. Cl. CPC H03K 3/013; H03L 7/08; H03L 7/0812; H03L 7/18; H03L 7/091; H03L 7/0891

(57) ABSTRACT

A low phase-noise phase locked loop (PLL). In an embodiment, the PLL includes a charge pump that includes a first switch, a second switch, a first resistor and a second resistor, which are connected in series. The first switch is provided between a power supply node and the first resistor, while the second switch is provided between the second resistor and a ground node. The junction of the first resistor and the second resistor provides the output of the charge pump. The first switch and the second switch are operated to be open or closed by outputs of a phase frequency detector of the PLL. In another embodiment, the charge pump and the low-pass filter of the PLL are implemented to process differential signals. Such implementation of the charge pump enables the PLL to generate an output signal with reduced phase-noise.

### PRIORITY CLAIM

The instant patent application claims priority from co-pending India provisional patent application entitled, “MINIMIZATION OF JITTER NOISE POWER CONTRIBUTED BY THE LOW FREQUENCY FORWARD PATH OF A PLL”, Application Number: 2397/CHE/2015, Filed: 11 May, 2015, naming as inventors Seedher et al, and is incorporated it its entirety herewith, to the extent not inconsistent with the content of the instant application.

### BACKGROUND

1. Technical Field

Embodiments of the present disclosure relate generally to Phase Locked Loops (PLL), and more specifically to a low phase-noise PLL.

2. Related Art

Phase locked loops (PLL) are often used to synthesize signals (such as clocks) with a desired frequency. Typically, a PLL contains a phase frequency detector (PFD), charge pump, a loop filter, a voltage controlled oscillator (VCO) and a divider. Depending on specific requirements, a PLL may include other components such as a delta-sigma modulator (DSM) (when fractional divide ratios are desired) and processing block(s) to receive user inputs specifying the desired frequency of the output signal of the PLL, etc. The PFD compares a fixed-frequency reference signal (typically generated by an oscillator) with a feedback signal (which is a frequency-divided version of the output signal of the PLL), and generates/activates error signals indicative of a phase difference between the reference signal and the feedback signal. The charge pump converts the error signals into corresponding electrical voltage, and the voltage is filtered by the low-pass filter. The output of the low-pass filter is used to adjust the frequency of the output signal (which is generated by the VCO) of the PLL. The closed loop feedback results in the frequency (Fvco) of the VCO output to equal a desired multiple of the frequency of the reference signal.

Ideally, the output signal of the PLL should have a frequency spectrum that has only one component, namely, the desired frequency (Fvco) of the output signal. However, various noise sources, such as those in the charge pump, power-supply used to power the charge pump, etc., often result in the output signal of the PLL (even at steady state, or locked-condition) to have non-zero noise components at frequencies on either sides of the desired frequency Fvco in the output spectrum. Phase noise at a frequency offset from Fvco generally refers to the ratio of the amplitude of a noise component at that frequency to the amplitude of the output signal at frequency Fvco.

A delay locked loop (DLL) may be viewed as a special case of a PLL, in which the VCO is replaced by a controllable delay line. A DLL compares (e.g., in a PFD) the phase of an output of the delay line with a reference signal to generate one or more error signals (similar to as in a PLL). The error signals may drive a charge pump that generates a voltage corresponding to the error signals. The voltage is filtered by a low-pass filter, and the magnitude of the filtered voltage controls the delay in the delay line. In general, in a DLL, phase error is measured, and phase is adjusted (in the delay line), whereas in a PLL, phase error is measured, and frequency is adjusted (in the VCO). The transfer function of a PLL is therefore one order higher than that of a DLL. As with a PLL, the output(s) of a DLL may also contain phase-noise.

It is generally desirable that the phase-noise in the output of a PLL/DLL be as low as possible. Several aspects of the present disclosure are directed to a low phase-noise PLL/DLL.

### BRIEF DESCRIPTION OF THE VIEWS OF DRAWINGS

Example embodiments of the present disclosure will be described with reference to the accompanying drawings briefly described below.

FIG. 1A is a block diagram of an example device in which several aspects of the present disclosure can be implemented.

FIG. 1B is an example timing diagram illustrating the operation of a phase frequency detector.

FIG. 1C is a diagram illustrating the details of a prior charge pump.

FIG. 2 is a circuit diagram illustrating the details of a charge pump in an embodiment of the present disclosure.

FIG. 3 is a circuit diagram illustrating the details of a charge pump in another embodiment of the present disclosure.

FIG. 4 is a diagram illustrating the interconnections between a common-mode control block and a low-pass filter of a PLL, in an embodiment of the present disclosure.

FIG. 5A is a circuit diagram illustrating the details of a common-mode control block in an embodiment of the present disclosure.

FIG. 5B is a circuit diagram illustrating the details of a common-mode control block in another embodiment of the present disclosure.

FIG. 5C is a circuit diagram illustrating the details of a common-mode control block in yet another embodiment of the present disclosure.

FIG. 6 is a diagram illustrating the details of a filter used in a PLL, in an embodiment of the present disclosure.

FIG. 7 is a diagram illustrating the details of a filter used in a PLL, in another embodiment of the present disclosure.

FIG. 8 is a block diagram of a system incorporating a PLL implemented according to several aspects of the present disclosure.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### 1. Overview

A low-phase noise phase locked loop (PLL) includes a charge pump that in turn includes a first switch, a second switch, a first resistor and a second resistor, which are connected in series. The first switch is provided between a power supply node and the first resistor, while the second switch is provided between the second resistor and a ground node. The junction of the first resistor and the second resistor provides the output of the charge pump. The first switch and the second switch are operated to be open or closed by outputs of a phase frequency detector of the PLL. In another embodiment, the charge pump and the low-pass filter of the PLL are implemented to process differential signals Implementation of the charge pump as noted above enables the PLL to generate an output signal with reduced phase-noise.

Several aspects of the present disclosure are described below with reference to examples for illustration. However, one skilled in the relevant art will recognize that the disclosure can be practiced without one or more of the specific details or with other methods, components, materials and so forth. In other instances, well-known structures, materials, or operations are not shown in detail to avoid obscuring the features of the disclosure. Furthermore, the features/aspects described can be practiced in various combinations, though only some of the combinations are described herein for conciseness.

### 2. Phase Locked Loop

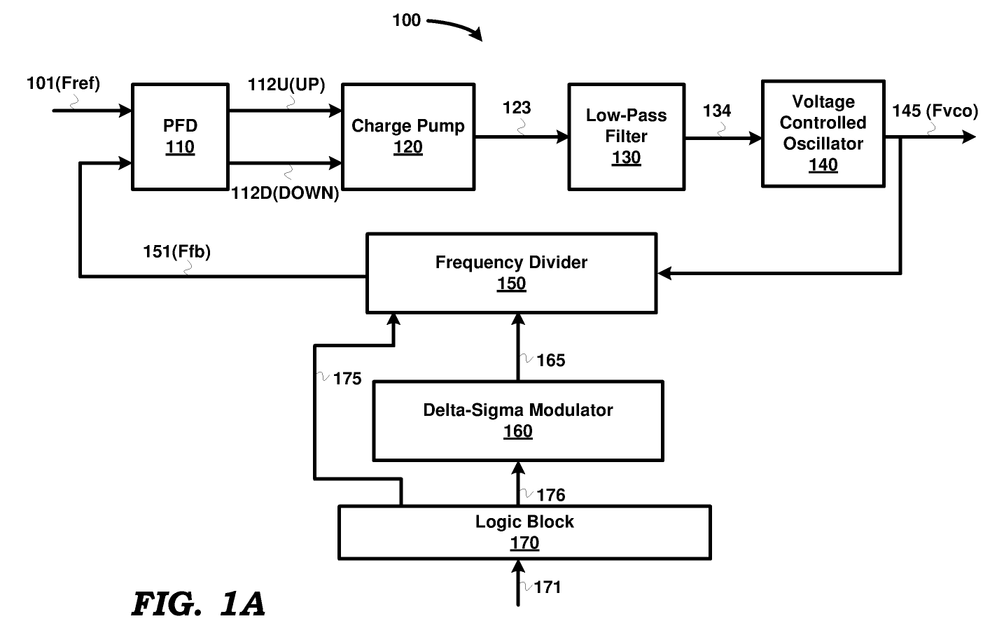

FIG. 1 is a block diagram of an example device in which several aspects of the present disclosure can be implemented. Phase locked loop (PLL) 100 (which can be used as a frequency synthesizer) of FIG. 1 is shown containing phase frequency detector (PFD) 110, charge pump 120, low-pass filter (LPF) 130, voltage controlled oscillator (VCO) 140, frequency divider 150, delta-sigma modulator (DSM) 160 and logic block 170. PLL 100 may be implemented as an integer-only PLL or a fractional PLL (as noted below), and may be implemented in integrated circuit (IC) form. While the description below is provided in the context of PLL, it is understood that several aspects of the present invention are applicable in the context of a DLL also.

VCO 140 generates an output signal (e.g., which may be used as a clock signal) Fvco on path 145, with the frequency of Fvco being determined by the (instantaneous) magnitude of voltage received on path 134. Fvco is typically a square wave or sinusoidal wave, and may be used by other systems (not shown) as a clock signal (after appropriate processing or conditioning, if so desired).

Frequency divider 150 receives Fvco as an input, divides the frequency of Fvco by a desired divide ratio, and provides the frequency-divided signal as a feedback signal Ffb on path 151. The divide ratio is an integer (N) if PLL 100 is implemented as an integer-only PLL/frequency synthesizer, and a fractional number (N.f), if PLL 100 is implemented as a fractional PLL/frequency synthesizer. In the fractional number N.f, N represents the integer portion, f represents the fractional portion, ‘.’ and represents the decimal point.

Logic block 170 receives a divide ratio (e.g., from a user) on path 171. When PLL 100 is implemented as a fractional PLL, logic block 170 forwards the fractional portion ‘f’ of the divide ratio to DSM 160 on path 176, and the integer portion of the divide ratio to frequency divider 150 on path 175. DSM 160 generates (in one of several known ways) a sequence of divide values corresponding to the fractional part, and provides the sequence to frequency divider 150 on path 165. Frequency divider 150 determines the divide ratio per cycle of reference frequency 101 by adding the inputs received on paths 175 and 165. Alternatively, such addition may be performed in a separate block, not shown, which would then provide the sum to frequency divider 150. When PLL 100 is implemented as an integer-only PLL, DSM 160 is not implemented, and logic block 170 forwards the divide ratio received on path 171 to frequency divider 150 on path 175. In an alternative embodiment, the input provided on path 171 represents a desired output frequency (for Fvco), and logic block 170 computes the corresponding divide ratio based on input 171. In yet other embodiments, other well-know techniques such as fractional dividers may be employed instead of using DSM 160.

PFD 110 receives as inputs, a reference frequency Fref on path 101 and feedback signal Ffb on path 151, and operates to generate error signals UP and DOWN on respective paths 112U and 112D. The ON (active) durations (illustrated in greater detail below with respect to FIG. 1B) of error signals UP and DOWN are proportional to the amount of phase by which Fref leads or lags Ffb respectively. Reference frequency Fref may be generated by an oscillator (not shown) contained within PLL 100, or provided external to PLL 100.

In the case of delay locked loop (DLL), VCO 140 is replaced by a voltage-controlled delay line, and components 150, 160 and 171 are not implemented. Instead, the output of the voltage-controlled delay line is directly provided as a feedback signal to PFD 110. Further, the voltage-controlled delay line may provide multiple outputs, each offset from each other by a phase, as is well known in the relevant arts.

The example timing diagram of FIG. 1B illustrates the manner in which UP and DOWN signals are generated. In FIG. 1B, the phase of Fref is shown as leading the phase of Ffb by an angle that corresponds to interval t181-t182. At time t181, Fref transitions to logic high. Consequently, UP transitions to logic high also at t181. At time t182, Ffb transitions to logic high. Consequently, DOWN transitions to logic high also at t182. Time intervals t182-t183 represents the ‘reset delay’ provided in PFD 110. Thus, signal UP is asserted (activated) for a duration which is the sum of the durations for which Fref leads Ffb and the reset delay. Signal DOWN on the other hand is not asserted for the duration t181-t182, but only for the duration of the reset delay. The reset delay is introduced to prevent a dead-zone in the response of PFD 110, as is well known in the relevant arts.

When, the phase of Fref lags that of Ffb (not shown in the Figures), DOWN is asserted (activated) for a duration which is the sum of the durations for which Fref lags Ffb and the reset delay. UP on the other hand is asserted only for the duration of the reset delay. For other values of phase lead (phase lag) of Fref with respect to Ffb, the width of UP (DOWN) will be correspondingly different. Reset delays are always added to UP and DOWN irrespective of the specific phase lead or phase lag between Fref and Ffb. The active-high logic of the UP and DOWN signals can be changed to active-low logic, with corresponding changes in the design of blocks like charge pump 120 and VCO 140, but the general description provided above still holds true.

Charge pump 120 converts the UP and DOWN outputs of PFD 110 to a voltage (provided on path 123). Path 123 may be single-ended or differential, depending on whether charge pump 120 is designed to provide a single-ended or differential output. While signals UP and DOWN have been noted as being applied to charge pump 120, signals derived from UP and/DOWN (e.g., logical inverse of the signals) may instead be applied to charge pump 120 depending on the specific design of charge pump 120.

LPF 130 is a low-pass filter and rejects frequency variations of the voltage at node 123 above a certain cut-off limit LPF 130 may be implemented to either process single-ended or differential signals, and path 134 may thus represent a single-ended output or a differential output. Further, and as illustrated with examples below, LPF 130 may be implemented to contain ‘proportional’ path and an ‘integrating’ path. In such embodiments, LPF 130 provides the respective ‘proportional’ output and ‘integrating’ output on separate paths (which may be referred to herein as 134P and 1341 respectively, although not shown in FIG. 1A), both of which are assumed to be represented by path 134 in FIG. 1B. The outputs 134P and 1341 may each also be either single-ended or differential.

VCO 140 generates Fvco with a frequency that is dependent on the magnitude of voltage (or voltages in case of separate ‘proportional’ and ‘integral’ outputs) 134. VCO 140 may be implemented with a single control-port on which to receive voltage 134 when LPF 130 generates only a single output (e.g., proportional output). When LPF 130 is implemented to generate both a proportional and an integral output, VCO 140 is implemented with two control ports, one to receive the proportional output and the other to receive the integral output.

The components/blocks of FIG. 1 may be designed to enable generation of Fvco with frequencies in a desired range by appropriate choice of the divide ratio provided by frequency divider 150.

As noted above, noise contributed by one or more components of PLL 100 may result in unacceptable levels of phase noise in the output signal 145. For example, in one prior approach, charge pump 120 is implemented with an active current source and an active current sink, as shown in FIG. 1C. Prior charge pump 190 is used in place of charge pump 120 of FIG. 1A. The current source 191 of prior charge pump 190 is connected to the output 197 (which corresponds to output 123 of FIG. 1A) when UP is active (switch 193 being closed), while the current sink 192 is connected to the output 197 when DOWN is active (switch 194 being closed). Current source 191 is typically implemented as a PMOS transistor (not shown) whose gate terminal is maintained at a constant voltage using a bias circuit. Similarly, Current source 191 is typically implemented as a NMOS transistor (not shown) whose gate terminal is maintained at a constant voltage using another bias circuit. The bias circuits used internally in current source 191 and current sink 192 are sources of noise, which translate to phase noise in output signal 145.

Further, in prior charge pump 190, switches 193 and 194 are not referred to supply or ground (i.e. are not directly connected to supply 199 or ground 198). This results in relatively longer times needed for closing and opening the switches, i.e., longer switching times. Further, reset-delay time may need to be larger than the switching time for the charge pump to avoid a dead zone in the PLL forward path characteristic. Hence, slower switching times of switches 193 and 194 translate to a requirement for a large reset time (during which both 191 and 192 are connected to node 197), which in turn implies that more noise is contributed from components 191 and 192 to output 197 (and therefore to more phase-noise in output 145).

The description is continued with illustration of components of a PLL according to the present disclosure.

### 3. Resistive DAC

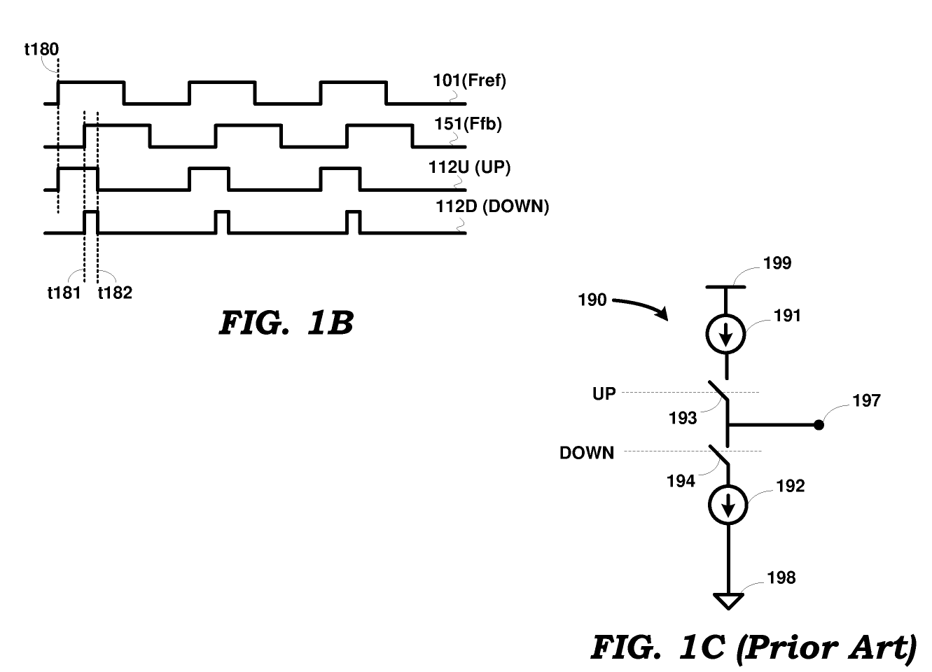

FIG. 2 is a circuit diagram illustrating the details of a charge pump in an embodiment of the present disclosure. Charge pump 200 of FIG. 2, which can be used in place of charge pump 120 of FIG. 1, is implemented as a resistive-DAC (digital-to-analog converter) circuit (or a switched-resistor DAC circuit), and is shown containing PMOS (P-Channel Metal Oxide Semiconductor) transistor 210, NMOS (N-Channel Metal Oxide Semiconductor) transistor 220, and resistors 230 and 240. Transistors 210 and 220 are employed as switches, and can be implemented using other types of components such as bipolar junction transistors, etc. Terminal 123 represents the output terminal of charge pump 200, and corresponds to similarly numbered terminal 123 in FIG. 1A.

The source and drain terminals of PMOS transistor 210 are respectively connected to power supply node (Vdd) 299 and one terminal of resistor 230. The other terminal of resistor 230 is connected to output terminal 123. The gate terminal of PMOS transistor 210 is connected to /UP 201. /UP 201 represents the logical inverse of 112U (UP), and is assumed to be generated within PFD 110.

The source and drain terminals of NMOS transistor 220 are respectively connected to ground node (GND) 298 and one terminal of resistor 240. The other terminal of resistor 240 is connected to output terminal 123. The gate terminal of NMOS transistor 220 is connected to DOWN 112D, which is generated by PFD 110.

In operation, when /UP is at logic low (i.e., when UP is at logic high), PMOS transistor 210 is switched ON (closed). Hence, Vdd 299 is connected to output terminal 123 via resistor 230, and a current (or equivalently charge) flows into output terminal 123, with the value of current being determined by the resistance of resistor 230. The value of the current is primarily determined by the resistor 230, supply voltage Vdd (299), and the output voltage of charge pump 200 that is determined by the loop dynamics (of PLL 100). The combination of switch 210 when closed, Vdd (299) and resistor 230 therefore represents a current source. PMOS transistor 210 remains closed for the duration for which /UP is at logic low.

When DOWN is at logic high, NMOS transistor 220 is switched ON (closed). Hence, output terminal 123 is connected to GND 298 via resistor 240, and a current (or equivalently charge) flows from output terminal 123 to GND 298, with the value of current being determined by the resistance of resistor 240 and the voltage on output terminal 123. The combination of switch 220 and resistor 240 represents a current sink. NMOS transistor 210 remains closed for the duration for which DOWN is at logic high. The resistances of resistors 230 and 240 may be designed to have a same value. The value of the resistance is determined by the overall loop dynamics in general, and practical considerations such as size of switches 210 and 220. When /UP is at logic low with DOWN being at logic high (as would occur during the reset interval), both transistors 210 and 220 are ON.

Charge pump 200 of FIG. 2, thus, operates as a pulse-width-modulated resistive DAC for converting phase difference between Fref and Ffb to a corresponding voltage on output terminal 123.

It may be observed from FIG. 2 that resistive DAC charge pump 200 does not employ any biasing circuitry. As a result, there is no noise contribution that otherwise might have occurred due to such biasing circuitry. Secondly, PMOS transistor 210 transistor switch 210 is referred to Vdd 299, while NMOS transistor switch 220 is referred to GND 298. As a result, all of the drive voltage (/UP for switch 210, and DOWN for switch 220) is available across gate and source terminals of the respective switches, thereby allowing for faster switching (ON to OFF, and OFF to ON) of switches 210 and 220. Faster switching in turn implies that the reset delay duration (which equals the duration in each Fref cycle for which both switches 210 and 220 are ON) to be relatively smaller than otherwise. Hence, the noise contribution by charge pump 200 in each reset-delay duration is smaller than otherwise (i.e., than if the switches were connected between the corresponding resistor and output terminal 123).

Further, in the steady state of operation of PLL 100, switches 210 and 220 would be ON for only a small fraction of the period of Fref, and thus the effective value of resistors 230 and 240 is very high (the resistor values would effectively be divided by the duty cycle of the switches, the duty cycle at steady state being a very small fraction). Hence, in steady state of operation (of PLL 100), switched resistor DAC 200 appears (and operates) as a high-resistance current source.

Due to one or more of the reasons noted above, PLL 100 implemented with resistive-DAC charge pump 200 in place of charge pump 120 would generate output signal 145 with lesser phase-noise in the steady state operation of PLL 100 (i.e., when PLL 100 is locked to Fref in terms of phase and frequency, and is generating the desired output frequency Fvco).

Another contributor of phase-noise in a PLL is noise from power supply Vdd that powers single-ended circuits such as resistive-DAC charge pump 200. In an alternative embodiment of the present disclosure, a resistive-DAC charge pump as well as the LPF 130 and VCO 140 are implemented in differential form, as described next.

### 4. Differential Charge Pump

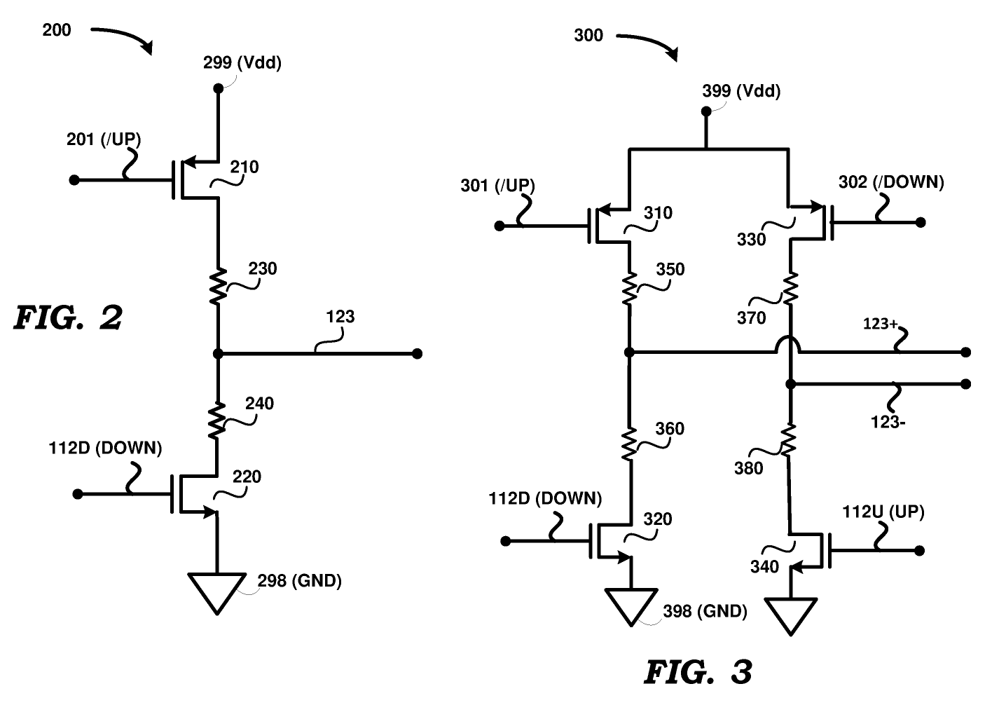

FIG. 3 is a circuit diagram of a resistive-DAC charge pump with differential outputs in an embodiment of the present disclosure. Resistive-DAC charge pump 300 is shown in FIG. 3 containing PMOS transistors 310 and 330, NMOS transistors 320 and 340, and resistors 350, 360, 370 and 380. Differential output terminals 123+ and 123− are assumed to be contained in path 123 of FIG. 1A.

The source and drain terminals of PMOS transistor 310 are respectively connected to power supply node (Vdd) 399 and one terminal of resistor 350. The other terminal of resistor 350 is connected to output terminal 123+. The gate terminal of PMOS transistor 310 is connected to /UP 301, which represents the logical inverse of 112U (UP), and is assumed to be generated within PFD 110. The source and drain terminals of NMOS transistor 320 are respectively connected to ground node (GND) 398 and one terminal of resistor 360. The other terminal of resistor 360 is connected to output terminal 123+. The gate terminal of NMOS transistor 320 is connected to DOWN 112D, which is generated by PFD 110.

The source and drain terminals of PMOS transistor 330 are respectively connected to power supply node (Vdd) 399 and one terminal of resistor 370. The other terminal of resistor 370 is connected to output terminal 123−. The gate terminal of PMOS transistor 330 is connected to /DOWN 302, which represents the logical inverse of 112D (DOWN), and is assumed to be generated within PFD 110. The source and drain terminals of NMOS transistor 340 are respectively connected to ground node (GND) 398 and one terminal of resistor 380. The other terminal of resistor 380 is connected to output terminal 123−. The gate terminal of NMOS transistor 340 is connected to 112U (UP), which is generated by PFD 110.

In operation, when /UP is at logic low (UP being at logic high), PMOS transistor 310 and NMOS transistor 340 are switched ON (closed). Hence, Vdd (399) is connected to output terminal 123+ via resistor 230, output terminal 123− is connected to GND 398 via resistor 380, and a constant current flows from output terminal 123+ to output terminal 123− via the corresponding components of a low-pass filter connected between nodes 123+ and 123−. The magnitude of such constant current is determined by the resistances of resistors 350 and 380, each of which may be implemented to have the same resistance. The combination of switches 310 and 340 and resistors 350 and 380 represents a constant current source. PMOS transistor 310 and NMOS transistor 340 remain closed for the duration for which UP is at logic high.

When DOWN is at logic high (/DOWN being at logic low), PMOS transistor 330 and NMOS transistor 320 are switched ON (closed). Hence, Vdd (399) is connected to output terminal 123− via resistor 230, output terminal 123+ is connected to GND via resistor 380, and a constant current flows from output terminal 123− to output terminal 123+ via the corresponding components of the low-pass filter connected between nodes 123+ and 123−. The magnitude of such constant current is determined by the resistances of resistors 370 and 360, each of which may be implemented to have the same resistance. Further, the resistance values of all of resistors 350, 360, 370 and 380 may be implemented to have the same value. The combination of switches 330 and 320 and resistors 370 and 360 represents another constant current source. PMOS transistor 330 and NMOS transistor 320 remain closed for the duration for which DOWN is at logic high.

In the steady state of operation of PLL 100, switches 310/340 and 320/330 would be ON for only a small fraction of the period of Fref, and thus the effective value of resistors 350 and 380, as well as 370 and 360, is very high. Hence, in the steady state of operation of PLL 100, switched resistor DAC 300 appears (and operates) as a high resistance current source.

Charge pump 300 of FIG. 3, thus, operates as a pulse-width-modulated resistive DAC for converting phase difference between Fref and Ffb to a corresponding voltage in differential form across differential output terminal pair 123+ and 123−. As with charge pump 200 of FIG. 2, charge pump 300 does not employ biasing circuitry for the current sources. Hence, there is no noise contribution that otherwise might have occurred due to such biasing circuitry. Further, PMOS switches 310 and 330 are referred to Vdd (399), while NMOS switches 320 and 340 are referred to GND (398). Thus, the switches can be operated at high speeds, thereby requiring only a relatively shorter reset delay duration, which in turn reduces noise contribution from charge pump 300. Further, the differential nature of the output of the charge pump 300 cancels any common-mode noise (on terminals 123+ and 123−) which might otherwise be present due to noise in power supply 399 (Vdd). PLL 100 implemented with charge pump 300 in place of charge pump 120 of FIG. 1 would, therefore, generate output signal 145 with lesser phase-noise, and would be able to lock faster.

Further, the use of a resistive pulse width modulated DAC structure such as charge pump 300 simplifies the design of the phase-to-charge conversion circuit (i.e. the charge pump) significantly. The simpler structure of DAC 300 implies a significantly smaller number of components, thereby making it easier to limit mismatches. Thus, the current (or charge) generated by the ‘up’ elements (switches 310 and 340, and resistors 350 and 380) can be ensured to equal the current (or charge) generated by the ‘down’ elements (switches 330 and 320, and resistors 370 and 360), thereby rendering the overall phase-to-charge conversion a highly linear function across positive and negative phase differences of Fref and Ffb. This is particularly useful for fractional-PLLs since the shaped quantization noise from the DSM modulator (used in fractional PLLs) can fold in-band due to non-linearity in the phase-to-charge conversion. This is an added advantage of a switched resistive-DAC-based phase-to-charge conversion.

When PLL 100 is implemented with differential charge pump 300 in place of charge pump 120 of FIG. 1, one or both of LPF 130 and VCO 140 is also implemented to process differential signals, as described next.

### 5. Differential Filter and Common-Mode Voltage Control

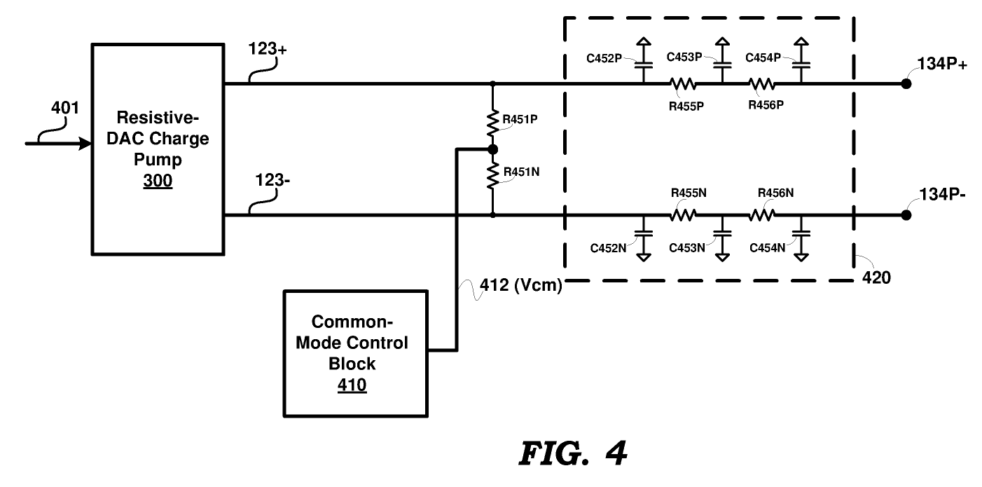

FIG. 4 is a diagram illustrating the details of a third-order low-pass filter (420) implemented to process the differential output 123+/123− of charge pump 300, in an embodiment of the present disclosure. Also shown in FIG. 4 are charge pump 300 of FIG. 3, and common-mode control block 410. Although common-mode control block 410 is shown separate from resistive-DAC charge pump 300, common-mode control block 410 may be deemed to be contained within resistive-DAC charge pump 300. Path 401 is assumed to contain the relevant outputs (UP, /UP, DOWN, /DOWN) of PFD 110.

LPF 420, which can be implemented in place of LPF 130 of FIG. 1A (with charge pump 300 implemented in place of charge pump 120), is shown containing resistors R455P, R455N, R456P, and R456N, and capacitors C452P, C452N, C453P, C453N, C454P and C454N, and represents a third-order low-pass filter. LPF420 suppresses or attenuates frequencies in the voltage across nodes 123+/123− above a desired threshold frequency (determined by the values of the resistors and capacitors of LPF 420), and provides a filtered voltage across differential outputs 134P+ and 134P− (which are deemed to be contained in path 134 of FIG. 1A). Terminals 134P+ and 134P− may be connected respectively to corresponding terminals of the ‘proportional’ control port of VCO 140.

Common-mode control block 410, in combination with resistors R451P and R451N, operates to set the common-mode voltage on each of differential paths 123+ and 123−. As is well known in the relevant arts, a common-mode voltage is a voltage that is common to both terminals of a differential signal. In general, a common-mode voltage may need to be set on each of paths 123+ and 123− to ensure sufficient (or desired) voltage swing across terminals 134P+ and 134P−, as well as for setting the input common-mode voltage requirement (if any) of the following circuit (here VCO 140).

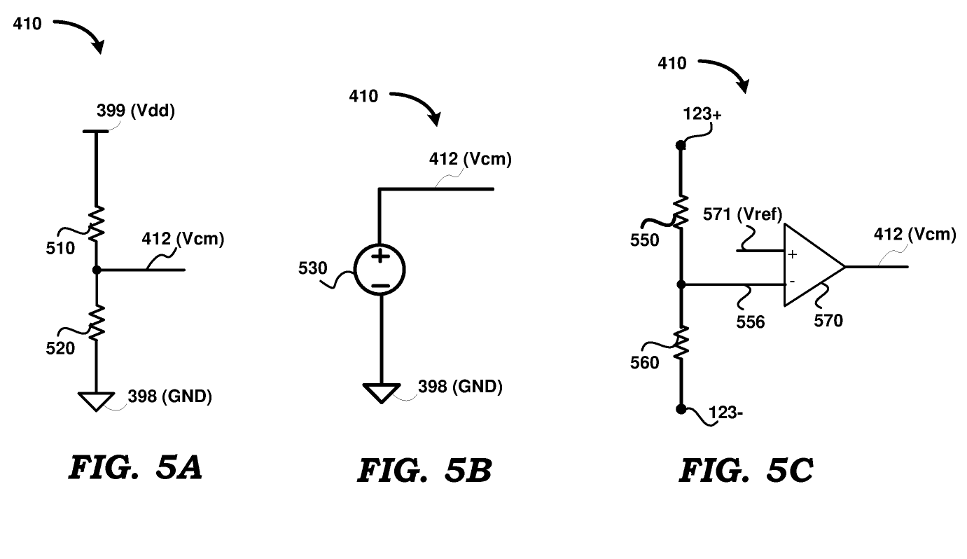

In an embodiment of the present disclosure, common-mode control block 410 is implemented as illustrated in FIG. 5A. Resistors 510 and 520 are connected in series between power supply node 399 (Vdd) and ground (398), and the voltage at the junction of the two resistors is provided as Vcm (412). Resistors 510 and 520 can be implemented to have equal resistances (example, in the mega-ohm range), such that Vcm equals Vdd/2. However, unequal resistance values can also be used for resistors 510 and 520.

In another embodiment of the present disclosure, common-mode control block 410 is implemented as illustrated in FIG. 5B. Voltage source 530 generates the desired value of Vcm, and can be implemented in one of several known ways.

In another embodiment of the present disclosure, common-mode control block 410 employs negative feedback, and is implemented as illustrated in FIG. 5C. Operational amplifier (OPAMP) 570 receives a reference voltage Vref on non-inverting (+) terminal 571. Resistors 550 and 560 are connected in series between terminals 123+ and 123− of charge pump 300, and the voltage at the junction of the two resistors is connected to the inverting input (−) of OPAMP 570. Feedback is provided via resistors R451P and R451N (shown in FIG. 4). In an embodiment, Vref equals Vdd/2, and resistors 550 and 560 have equal resistances. The negative feedback ensures that Vcm is maintained at a pre-defined voltage that is fed at the Vref port 571. In other embodiments, OPAMP 570 can be replaced with other amplifier structures, as would be well known to one skilled in the relevant arts.

The use of a third order filter to illustrate the arrangement of the proportional path with a common mode setting arrangement is provided merely as an example. The arrangement can be extended to a similar arrangement using filters of other orders also, as would be apparent to one skilled in the relevant arts.

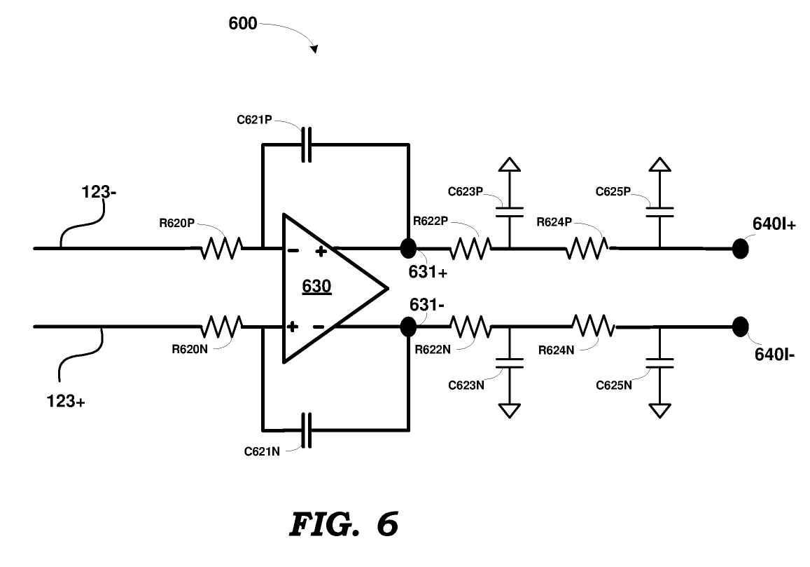

The output 134P+/134P− of LPF 420 of FIG. 4 is proportional to its input 123+/123−. In another embodiment of the present disclosure, an integrating filter is provided in addition to LPF420 (i.e., both a proportional path as well as an integrating path are provided), and is shown in the diagram of FIG. 6. Integrating filter 600 is shown containing differential-output OPAMP 630, resistors R620P, R620N, R622P, R622N, R624P, R624N, and capacitors C621P, C621N, C623P, C623N, C625P and C625N. The combination of OPAMP 630, resistors R620P, R620N, capacitors C621P and C621N represents an integrator, and generates, across terminals 631+ and 631−, the time integral of the voltage across input terminals 123+ and 123−. Components R622P, R622N, C623P, C623N, R624P, R624N, C625P and C625N form an additional second-order low-pass filter in the integrating path. The output of LPF 600 is provided in differential form across terminals 6401+ and 6401−, and may respectively be connected to corresponding terminals of the integral control port of VCO 140. The use of an integrating filter makes the PLL 100 a type-II PLL. In other embodiments, OPAMP 630 can be replaced with other amplifier structures, as would be well known to one skilled in the relevant arts. The bandwidth of the integrating path represented by filter 600 may be smaller than that of the proportional path represented by filter 420.

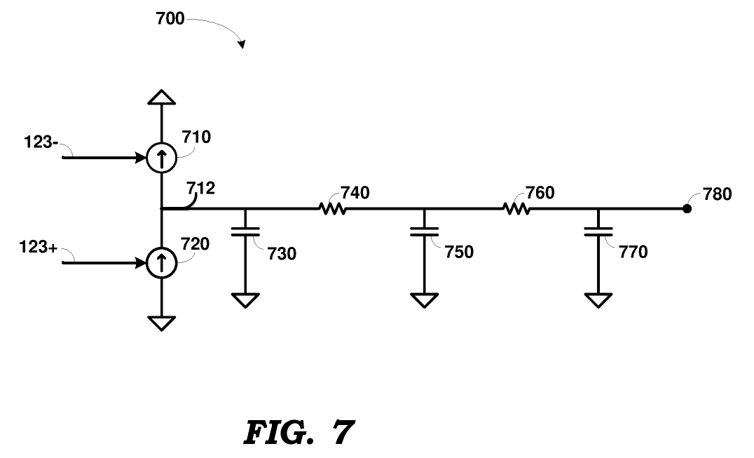

In an alternative embodiment of the present disclosure, the filter in the integrating path is implemented as a Gm-C (transconductance-capacitance) filter, as illustrated in FIG. 7 (rather than as shown in FIG. 6), and provides a single-ended output (rather than differential as in FIG. 6). It is to be understood that in other embodiments, the output of such Gm-C filter can be implemented to be in differential form also. Further, the inputs and outputs can also be implemented respectively in differential and single-ended form, etc. Filter 700 of FIG. 7 is shown containing transconductance amplifiers 710 and 720, capacitors 730, 750 and 770, and resistors 740 and 760. Transconductance amplifier 720 sources a current into terminal 712, with the magnitude of the current being proportional by a factor Gm1 (Gm1 being the transconductance of amplifier 720) to the voltage at node 123+. Transconductance amplifier 710 sinks a current from terminal 712 to GND, with the magnitude of the current being proportional by a factor Gm2 (Gm2 being the transconductance of amplifier 720) to the voltage at node 123+. In an embodiment, Gm1 equals Gm2. The currents sourced and sunk by amplifiers 710 and 720 generate a voltage across capacitor 730, and the voltage is filtered by the low-pass filter formed by components 740, 750, 760 and 770, to generate a filtered voltage at 780 in single-ended form. Node 780 is deemed to be contained in path 134 of FIG. 1A, and may be connected to the integral control port of VCO 140.

PLL 100 implemented according to aspects of the present disclosure generates an output signal 145 which may contain relatively less phase-noise, and may be incorporated in a larger system, as illustrated next.

### 6. System

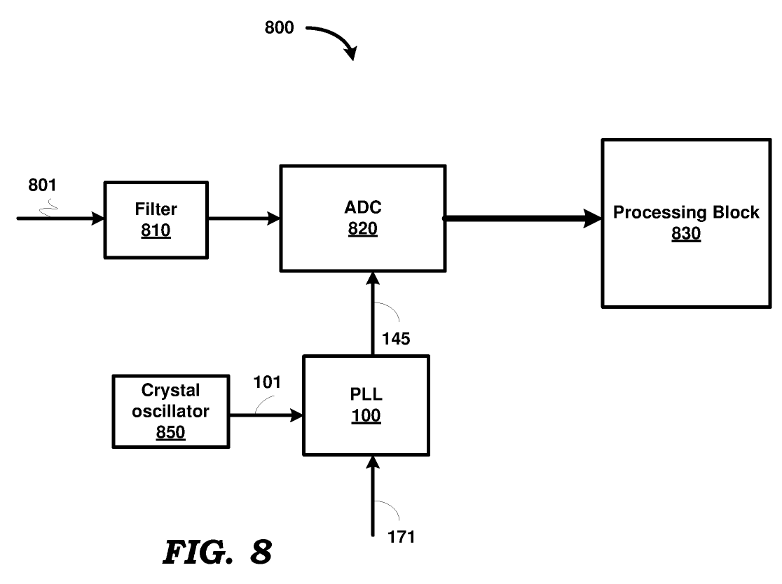

FIG. 8 is a block diagram of a system in which a PLL implemented according to aspects of the present disclosure can be used. Data converter system (system) 800 is shown containing filter 810, analog to digital converter (ADC) 820, processing block 830, crystal oscillator 850 and PLL 100.

Filter 810, which may be an anti-aliasing filter of system 100, receives an analog signal on path 801, and provides a filtered signal (low-pass or band-pass filtered) to ADC 820. ADC 820 receives a sampling clock on path 145 from PLL 100, and generates digital codes representing the magnitude of the received filter signal at time instances (e.g., rising edges) specified by sampling clock 145. Processing block 830 receives the digital codes, and processes the digital codes in a desired manner.

Crystal oscillator 850 generates reference frequency 101 at a fixed (desired) frequency. PLL 100 receives, on path 171, either a divide ratio (integer or fractional) or an input representing the desired output frequency (Fvco), and reference frequency 101, and generates sampling clock 145 at a frequency determined by the divide ratio and the frequency reference 101. Due to the implementation of PLL 100 as described in detail above, sampling clock 145 has very low phase-noise. As a result, system 100 can be implemented as a high-speed, high-accuracy data converter system.

### 7. Conclusion

References throughout this specification to “one embodiment”, “an embodiment”, or similar language means that a particular feature, structure, or characteristic described in connection with the embodiment is included in at least one embodiment of the present disclosure. Thus, appearances of the phrases “in one embodiment”, “in an embodiment” and similar language throughout this specification may, but do not necessarily, all refer to the same embodiment.

While in the illustrations of FIGS. 1 through 8, although terminals/nodes are shown with direct connections to (i.e., “connected to”) various other terminals, it should be appreciated that additional components (as suited for the specific environment) may also be present in the path, and accordingly the connections may be viewed as being “electrically coupled” to the same connected terminals. On the other hand, when a node is “connected to” or “directly connected to” another node, it means that there are no intervening components between the nodes, and the two nodes are effectively a single node or the connection between them is an electrical short (zero or very low resistance).

Further, it should be appreciated that the specific type of transistors (such as NMOS, PMOS, etc.) noted above are merely by way of illustration. However, alternative embodiments using different configurations and transistors will be apparent to one skilled in the relevant arts by reading the disclosure provided herein. For example, NMOS transistors and PMOS transistors may be swapped, while also interchanging the connections to power and ground terminals. Accordingly, in the instant application, the power and ground terminals are referred to as constant reference potentials, and may be derived, for example, from low-noise circuits having good PSRR (power-supply rejection ratio). The source (emitter) and drain (collector) terminals (through which a current path is provided when turned ON and an open path is provided when turned OFF) of transistors are in general termed as current terminals, and the gate (base) terminal is termed as a control terminal.

While various embodiments of the present disclosure have been described above, it should be understood that they have been presented by way of example only, and not limitation. Thus, the breadth and scope of the present disclosure should not be limited by any of the above-described embodiments, but should be defined only in accordance with the following claims and their equivalents.

What is claimed is:

1. A circuit comprising:
a first switch coupled to receive a first signal of a set of signals, said first switch operable to be open when said first signal is at a first logic level, and to be closed when said first signal is at a second logic level, wherein said first switch contains a first terminal and a second terminal, said first terminal of said first switch being electrically coupled to said second terminal of said first switch when said first switch is closed, said first terminal of said first switch being electrically disconnected from said second terminal of said first switch when said first switch is open, wherein said first terminal of said first switch is directly connected to a first constant reference potential node;
a first resistor, wherein a first terminal of said first resistor is coupled to said second terminal of said first switch, wherein a second terminal of said first resistor is coupled to an output node of said circuit;
a second resistor, wherein a first terminal of said second resistor is coupled to said output node; and
a second switch coupled to receive a second signal of said set of signals, said second switch operable to be open when said second signal is at a first logic level, and to be closed when said second signal is at a second logic level, wherein said second switch contains a first terminal and a second terminal, said first terminal of said second switch being electrically coupled to said second terminal of said second switch when said second switch is closed, said first terminal of said second switch being electrically disconnected from said second terminal of said second switch when said second switch is open, wherein said first terminal of said second switch is coupled to a second terminal of said second resistor, and wherein said second terminal of said second switch is directly connected to a second constant reference potential node.

2. The circuit of claim 1, wherein said circuit is comprised in a phase locked loop (PLL), wherein said set of signals are representative of a phase difference between a reference signal of said PLL and an output signal of said PLL, wherein said circuit is designed to generate a voltage representative of said phase difference, said circuit receiving a power supply for operation across said first constant reference potential node and said second constant reference potential node.

3. The circuit of claim 1, wherein said circuit is comprised in a delay locked loop (DLL), wherein said set of signals are representative of a phase difference between a reference signal of said DLL and an output signal of said DLL, wherein said circuit is designed to generate a voltage representative of said phase difference, said circuit receiving a power supply for operation across said first constant reference potential node and said second constant reference potential node.

4. The circuit of claim 2, wherein said output node is coupled to an input node of a low-pass filter of said PLL, wherein said circuit generates a voltage at said output node in single-ended form, said voltage being representative of said phase difference.

5. The circuit of claim 1, further comprising:
a third switch coupled to receive a third signal, said third signal being a logical inverse of said second signal, said third switch operable to be open when said third signal is at a first logic level, and to be closed when said third signal is at a second logic level, wherein said third switch contains a first terminal and a second terminal, said first terminal of said third switch being electrically coupled to said second terminal of said third switch when said third switch is closed, said first terminal of said third switch being electrically disconnected from said second terminal of said third switch when said third switch is open, wherein said first terminal of said third switch is directly connected to said first constant reference potential node;
a third resistor, wherein a first terminal of said third resistor is coupled to a second terminal of said third switch, wherein a second terminal of said third resistor is coupled to another output node of said circuit;
a fourth resistor, wherein a first terminal of said fourth resistor is coupled to said another output node; and
a fourth switch coupled to receive a fourth signal, said fourth signal being a logical inverse of said first signal, said fourth switch operable to be open when said fourth signal is at a first logic level, and to be closed when said fourth signal is at a second logic level, wherein said fourth switch contains a first terminal and a second terminal, said first terminal of said fourth switch being electrically coupled to said second terminal of said fourth switch when said fourth switch is closed, said first terminal of said fourth switch being electrically disconnected from said second terminal of said fourth switch when said fourth switch is open, wherein said first terminal of said fourth switch is coupled to a second terminal of said fourth resistor, and wherein a second terminal of said fourth switch is directly connected to said second constant reference potential node,
wherein said circuit generates a voltage across said output node and said another output node in differential form.

6. The circuit of claim 5, further comprising a common-mode control block to generate a common-mode voltage at each of said output node and said another output node.

7. The circuit of claim 6, wherein said output node and said another output node are coupled to corresponding input nodes of a differential low-pass filter.

8. A Phase Locked Loop (PLL) comprising:
a phase frequency detector (PFD) to receive a reference frequency and a feedback frequency, said PFD to generate a set of error signals representative of a phase difference between said reference frequency and said feedback frequency;
a resistive-DAC (digital to analog converter) charge pump coupled to one or more of said set of error signals, and to generate a corresponding voltage;
a low-pass filter (LPF) coupled to receive said corresponding voltage, and to filter said voltage to generate a filtered voltage;
a voltage controlled oscillator (VCO) coupled to receive said filtered voltage, and to generate an output signal; and
a frequency divider coupled to receive said output signal, and to divide a frequency of said output signal to generate said feedback frequency,
wherein said resistive-DAC charge pump comprises:
a first switch coupled to receive a first signal of a set of signals, said first switch operable to be open when said first signal is at a first logic level, and to be closed when said first signal is at a second logic level, wherein said first switch contains a first terminal and a second terminal, said first terminal of said first switch being electrically coupled to said second terminal of said first switch when said first switch is closed, said first terminal of said first switch being electrically disconnected from said second terminal of said first switch when said first switch is open, wherein said first terminal of said first switch is directly connected to a first constant reference potential node;
a first resistor, wherein a first terminal of said first resistor is coupled to said second terminal of said first switch, wherein a second terminal of said first resistor is coupled to an output node of said circuit;
a second resistor, wherein a first terminal of said second resistor is coupled to said output node; and
a second switch coupled to receive a second signal of said set of signals, said second switch operable to be open when said second signal is at a first logic level, and to be closed when said second signal is at a second logic level, wherein said second switch contains a first terminal and a second terminal, said first terminal of said second switch being electrically coupled to said second terminal of said second switch when said second switch is closed, said first terminal of said second switch being electrically disconnected from said second terminal of said second switch when said second switch is open, wherein said first terminal of said second switch is coupled to a second terminal of said second resistor, and wherein said second terminal of said second switch is directly connected to a second constant reference potential node.

9. The PLL of claim 8, wherein said output node is coupled to an input node of said LPF, wherein said resistive-DAC charge pump provides said corresponding voltage at said output node in single-ended form.

10. The PLL of claim 8, wherein said resistive-DAC charge pump further comprises:
a third switch coupled to receive a third signal, said third signal being a logical inverse of said second signal, said third switch operable to be open when said third signal is at a first logic level, and to be closed when said third signal is at a second logic level, wherein said third switch contains a first terminal and a second terminal, said first terminal of said third switch being electrically coupled to said second terminal of said third switch when said third switch is closed, said first terminal of said third switch being electrically disconnected from said second terminal of said third switch when said third switch is open, wherein said first terminal of said third switch is directly connected to said first constant reference potential node;
a third resistor, wherein a first terminal of said third resistor is coupled to a second terminal of said third switch, wherein a second terminal of said third resistor is coupled to another output node of said circuit;
a fourth resistor, wherein a first terminal of said fourth resistor is coupled to said another output node; and
a fourth switch coupled to receive a fourth signal, said fourth signal being a logical inverse of said first signal, said fourth switch operable to be open when said fourth signal is at a first logic level, and to be closed when said fourth signal is at a second logic level, wherein said fourth switch contains a first terminal and a second terminal, said first terminal of said fourth switch being electrically coupled to said second terminal of said fourth switch when said fourth switch is closed, said first terminal of said fourth switch being electrically disconnected from said second terminal of said fourth switch when said fourth switch is open, wherein said first terminal of said fourth switch is coupled to a second terminal of said fourth resistor, and wherein a second terminal of said fourth switch is directly connected to said second constant reference potential node,
wherein said resistive-DAC charge pump provides said corresponding voltage across said output node and said another output node in differential form.

11. The PLL of claim 10, wherein said resistive-DAC charge pump further comprises a common-mode control block to generate a common-mode voltage at each of said output node and said another output node.

12. The PLL of claim 11, wherein said common-mode control block employs negative feedback.

13. The PLL of claim 11, wherein said LPF is designed to process differential signals and comprises a first input terminal and a second input terminal, wherein said output node is coupled to said first input terminal, and said another output node is coupled to said second input terminal.

14. The PLL of claim 11, wherein said LPF comprises a first set of resistors and capacitors coupled to said output node, and a second set of resistors and capacitors coupled to said another output node, wherein said first set of resistors and capacitors and said second set of resistors and capacitors form a third order filter, wherein said LPF generates, across a first pair of differential terminals, a filtered output voltage that is proportional to said corresponding voltage, wherein respective terminals in said first pair of differential terminals are coupled to corresponding terminals of a proportional control port of said VCO.

15. The PLL of claim 14, further comprising a second low-pass filter to generate another output voltage in differential form across a second pair of differential terminals, said another output voltage representing a filtered time integral of said corresponding voltage, wherein respective terminals in said first pair of differential terminals are coupled to corresponding terminals of an integral control port of said VCO.

16. The PLL of claim 14, further comprising a third-low pass filter to generate another output voltage in single-ended form on an output terminal, said another output voltage representing a filtered time integral of said corresponding voltage, wherein said third-low pass filter comprises a pair of transconductance amplifiers, wherein said output terminal is coupled to a single-ended integral control port of said VCO.

17. A system comprising:
an analog to digital convert (ADC) coupled to receive an analog signal, said ADC to sample said analog signal at corresponding sampling instances of a sampling clock, and to generate a sequence of digital codes representing said analog signal;
an oscillator to generate a reference frequency;
a phase locked loop (PLL) to generate said sampling clock; and
a processing block to process said sequence of digital codes,
wherein said PLL comprises:
a phase frequency detector (PFD) to receive a reference frequency and a feedback frequency, said PFD to generate a set of error signals representative of a phase difference between said reference frequency and said feedback frequency;
a resistive-DAC (digital to analog converter) charge pump coupled to one or more of said set of error signals, and to generate a corresponding voltage;
a low-pass filter (LPF) coupled to receive said corresponding voltage, and to filter said voltage to generate a filtered voltage;
a voltage controlled oscillator (VCO) coupled to receive said voltage, and to generate an output signal; and
a frequency divider coupled to receive said output signal, and to divide a frequency of said output signal to generate said feedback frequency,
wherein said resistive-DAC charge pump comprises:
a first switch coupled to receive a first signal of a set of signals, said first switch operable to be open when said first signal is at a first logic level, and to be closed when said first signal is at a second logic level, wherein said first switch contains a first terminal and a second terminal, said first terminal of said first switch being electrically coupled to said second terminal of said first switch when said first switch is closed, said first terminal of said first switch being electrically disconnected from said second terminal of said first switch when said first switch is open, wherein said first terminal of said first switch is directly connected to a first constant reference potential node;
a first resistor, wherein a first terminal of said first resistor is coupled to said second terminal of said first switch, wherein a second terminal of said first resistor is coupled to an output node of said circuit;
a second resistor, wherein a first terminal of said second resistor is coupled to said output node; and
a second switch coupled to receive a second signal of said set of signals, said second switch operable to be open when said second signal is at a first logic level, and to be closed when said second signal is at a second logic level, wherein said second switch contains a first terminal and a second terminal, said first terminal of said second switch being electrically coupled to said second terminal of said second switch when said second switch is closed, said first terminal of said second switch being electrically disconnected from said second terminal of said second switch when said second switch is open, wherein said first terminal of said second switch is coupled to a second terminal of said second resistor, and wherein said second terminal of said second switch is directly connected to a second constant reference potential node.

18. The system of claim 17, wherein said output node is coupled to an input node of said LPF, wherein said resistive-DAC charge pump provides said corresponding voltage at said output node in single-ended form.

19. The system of claim 17, wherein said resistive-DAC charge pump further comprises:
a third switch coupled to receive a third signal, said third signal being a logical inverse of said second signal, said third switch operable to be open when said third signal is at a first logic level, and to be closed when said third signal is at a second logic level, wherein said third switch contains a first terminal and a second terminal, said first terminal of said third switch being electrically coupled to said second terminal of said third switch when said third switch is closed, said first terminal of said third switch being electrically disconnected from said second terminal of said third switch when said third switch is open, wherein said first terminal of said third switch is directly connected to said first constant reference potential node;
a third resistor, wherein a first terminal of said third resistor is coupled to a second terminal of said third switch, wherein a second terminal of said third resistor is coupled to another output node of said circuit;
a fourth resistor, wherein a first terminal of said fourth resistor is coupled to said another output node; and
a fourth switch coupled to receive a fourth signal, said fourth signal being a logical inverse of said first signal, said fourth switch operable to be open when said fourth signal is at a first logic level, and to be closed when said fourth signal is at a second logic level, wherein said fourth switch contains a first terminal and a second terminal, said first terminal of said fourth switch being electrically coupled to said second terminal of said fourth switch when said fourth switch is closed, said first terminal of said fourth switch being electrically disconnected from said second terminal of said fourth switch when said fourth switch is open, wherein said first terminal of said fourth switch is coupled to a second terminal of said fourth resistor, and wherein a second terminal of said fourth switch is directly connected to said second constant reference potential node,
wherein said resistive-DAC charge pump provides said corresponding voltage across said output node and said another output node in differential form.

20. The system of claim 19, wherein said resistive-DAC charge pump further comprises a common-mode control block to generate a common-mode voltage at each of said output node and said another output node.
